(19) United States
(12) Patent Application Publication
(10) Pub. No.: US 2024/0422910 A1
(43) Pub. Date: Dec. 19, 2024

(54) ALUMINUM FLEXIBLE PRINTED CIRCUIT BOARD ASSEMBLY AND PREPARATION METHOD THEREOF

(71) Applicant: Taicang Manaflex Technology Co., Ltd., Taicang City (CN)

(72) Inventors: Robert C. LANE, Las Vegas, NV (US); Xiaolou HUANG, Longueuil (CA)

(21) Appl. No.: 18/740,585

(22) Filed: Jun. 12, 2024

(30) Foreign Application Priority Data
Jun. 13, 2023 (CN) 202310696796.8

(51) Int. Cl. H05K 1/14; H05K 1/09

(52) U.S. Cl. CPC H05K 1/142; H05K 1/09

(57) ABSTRACT

An aluminum flexible printed circuit board assembly and a preparation method. The aluminum flexible printed circuit board assembly comprises a first circuit board and a second circuit board, the main circuit board is a flexible printed circuit board, and the two end parts of the main circuit board are communicated with the first circuit board; the branch circuit boards are flexible printed circuit boards, one end parts of the plurality of branch circuit boards are respectively communicated with the surface of the main circuit board, and the other end parts of the plurality of branch circuit boards are respectively communicated with the second circuit board; the main circuit board is provided with a first aluminum circuit layer and a first insulating layer, and the branch circuit board is provided with a second aluminum circuit layer and a second insulating layer.

### CROSS-REFERENCE TO RELATED APPLICATION

This application claims priority to and the benefit of Chinese Utility Model application No. 202310696796.8, filed Jun. 13, 2023, the entire disclosure of which is incorporated by reference in its entirety.

### TECHNICAL FIELD

The present invention relates to the technical field of electrical connectors, and in particular to an aluminum flexible circuit board that replaces a copper core wire harness.

### BACKGROUND TECHNOLOGY

The existing technology is to remove the insulation layer at both ends of the copper wire to crimp the terminal, and then insert the terminal into the connector to adapt to the counterpart connector. When the number of lines is large and the length of the lines is long, the weight of the wiring harness is large, and it is very time-consuming and difficult to organize and align the lines. If a fault occurs after the line has been installed, troubleshooting requires finding both ends of the specific line for replacement, so troubleshooting is also time-consuming and laborious.

### SUMMARY

The object of the present invention is to provide an aluminum flexible circuit board that can replace the copper core wire harness to overcome the shortcomings of the prior art.

In order to achieve the above objects, the present invention provides the following technical solutions:
The invention discloses an aluminum flexible printed circuit board assembly, which includes:
The first circuit board and the second circuit board;
A main circuit board, the main circuit board is a flexible printed circuit board, and both ends of the main circuit board are connected to the first circuit board;
Branch circuit board, the branch circuit board is a flexible printed circuit board, and one end of several branch circuit boards is connected to the surface of the main circuit board, and the other end is connected to the second circuit board respectively;
The main circuit board has a first aluminum circuit layer and a first insulating layer, and the branch circuit board has a second aluminum circuit layer and a second insulating layer.

Further, the first circuit board includes a plurality of first connectors and first pads respectively provided corresponding to the plurality of first connectors.

Further, two ends of the first aluminum circuit layer respectively form second bonding pads on the surface of the main circuit board, and the second bonding pads are connected to the corresponding first bonding pads.

Further, the second bonding pad is welded to the corresponding first bonding pad, and an insulating sealant is provided at the welding point.

Further, both ends of the main circuit board are fixedly connected to the corresponding first circuit board through second connectors, so that the second soldering pad is connected to the corresponding first soldering pad.

Further, a plurality of third pads for connecting branch circuits are provided on the surface of the main circuit board.

Further, both ends of the second aluminum circuit layer form fourth bonding pads on the surface of the branch circuit board respectively, and the fourth bonding pads are respectively connected to the corresponding third bonding pads and the second circuit board.

Further, the fourth bonding pad is welded to the corresponding third bonding pad, and an insulating sealant is provided at the welding point.

Further, the branch line is fixed to the corresponding main line through a third connector, and the fourth soldering pad is connected to the corresponding third soldering pad.

Further, the second circuit board includes a plurality of fourth connectors and fifth pads respectively provided corresponding to the fourth connectors.

Further, the fifth pad is welded to the corresponding fourth pad, and an insulating sealant is provided at the welding point.

Further, the branch line is fixed to the corresponding second circuit board through a fifth connector, and the fourth soldering pad is connected to the corresponding fifth soldering pad.

Further, the main circuit board is provided with a ground layer.

Further, both the main circuit board and the branch circuit board are provided with spare pads.

Further, the main circuit board and/or the branch circuit board are provided with a mounting portion.

The invention also discloses a method for preparing an aluminum flexible printed circuit board assembly, which includes the following steps:
S1. Prepare a first circuit board, a main circuit board, a branch circuit board and a second circuit board, wherein the first circuit board includes a plurality of first connectors and first pads respectively provided corresponding to the first connectors, the second circuit board includes a plurality of fourth connectors and fifth pads respectively provided corresponding to the fourth connectors. The main circuit board is a flexible printed circuit board, including at least two layers of first insulating layers and a plurality of first insulating layers. The first aluminum circuit layer between the two first insulating layers, the branch circuit board is a flexible printed circuit board, including two second insulating layers and a plurality of second aluminum circuit layers disposed between the two second insulating layers;
S2. Fix and connect the two ends of the main circuit board to the corresponding first circuit board, wherein the two ends of the main circuit board are respectively provided with second soldering pads, and the first circuit board is provided with a first soldering pad. pad, the second pad is connected to the corresponding first pad, and a plurality of third pads for connecting branch circuit boards are provided on the surface of the main circuit board;
S3. Fix one end of the branch circuit board and connect it to the second circuit board;
S4. Fix the other end of the branch circuit board and connect it to the main circuit board;
Wherein, fourth soldering pads are respectively provided at both ends of the branch circuit board, and fifth soldering pads are provided on the second circuit board. The two fourth soldering pads are respectively connected to the corresponding third soldering pads and the fifth soldering pads.

Further, in the above preparation method, the preparation process of the main circuit board includes the following steps:
S11. Use a laser cutting machine to cut the first aluminum circuit layer and the first insulation layer, and after the cutting is completed, roll them into rolls for use;
S12. Install the first aluminum circuit layer coil and the first insulation layer coil to the corresponding retracting and unwinding shaft of the roll-to-roll laser processing machine;
S13. Use the CCD alignment camera to align the first aluminum circuit layer and the corresponding first insulation layer;
S14. The first aluminum circuit layer and the first insulation layer are hot-pressed and formed at a temperature of 140° C. through a heating wheel to form a single-layer circuit board structure;
S15. Repeat steps S11 to S14;
S16. Bond two or more single-layer circuit board structures through a double-sided adhesive layer to form a circuit board structure with two or more layers.

Further, the laser cutting machine is a roll-to-roll laser cutting machine, and after the waste material is removed, the first aluminum circuit layer is formed.

Further, the laser cutting machine uses an ablation method to cut the first aluminum circuit layer.

Further, the first bonding pad and the fifth bonding pad are respectively soldered with nickel-plated aluminum sheets and welded to the corresponding main circuit board and branch circuit board.

Further, the second bonding pad and the fourth bonding pad connected to the second circuit board are sintered with a nickel layer.

Further, in the above preparation method, the sintering of the nickel layer includes the following steps:
S17. First cover the aluminum foil surface of the second pad or the fourth pad with a layer of nickel paste through silk screen printing;
S18. Use the laser to heat the aluminum sheet coated with nickel paste with a continuous power of 15 W to 250 W, leaving the nano-nickel powder to cover the aluminum sheet.
S19. Use the laser to reheat the surface layer of the aluminum sheet with nano-nickel powder at a continuous power of 200 W to 500 W.

Compared with the existing technology, the advantage of the present invention is that the aluminum flexible circuit board that replaces the copper core wire harness has a simple structure, uses the aluminum flexible circuit board to replace the copper core wire harness, reduces production costs and overall weight, and facilitates disassembly and line maintenance. and repair.

### BRIEF DESCRIPTION OF THE FIGURES

In order to explain the embodiments of the present invention more clearly, the drawings needed to be used in the description of the embodiments or the prior art will be briefly introduced below. Obviously, the drawings in the following description are only some embodiments recorded in the present invention. For those of ordinary skill in the art, other drawings can be obtained based on these drawings without exerting creative efforts.

FIG. 1 is a schematic structural diagram of an aluminum flexible circuit board that replaces a copper core wire harness in a specific embodiment of the present invention.

FIG. 2 shows a schematic diagram of the connection between the first circuit board and the main circuit in a specific embodiment of the present invention.

FIG. 3 is a schematic cross-sectional view of the connection point between the first circuit board and the main circuit in a specific embodiment of the present invention.

FIG. 4 shows a schematic structural diagram of the second pad in a specific embodiment of the present invention.

FIG. 5 shows a schematic structural diagram of the third pad in a specific embodiment of the present invention.

FIG. 6 shows a schematic structural diagram of an insulating sealant in a specific embodiment of the present invention.

FIG. 7 shows a schematic diagram of the connection between the branch line and the second circuit board in a specific embodiment of the present invention.

### DESCRIPTION OF EMBODIMENTS

The technical solutions in the embodiments of the present invention will be described in detail below with reference to the accompanying drawings in the embodiments of the present invention. Obviously, the described embodiments are only some, not all, of the embodiments of the present invention. Based on the embodiments of the present invention, all other embodiments obtained by those of ordinary skill in the art without any creative work fall within the scope of protection of the present invention.

In the description of the present invention, it should be noted that the “or” includes the relationship of “and”. The “and” is equivalent to the Boolean logical operator “and”, the “or” is equivalent to the Boolean logical operator “or”, and “and” is a subset of “or”.

It will be understood that, although the terms “first,” “second,” etc. may be used herein to describe various elements, these elements should not be limited by these terms. These terms are only used to distinguish one element from another element. Thus, a first element could be termed a second element without departing from the teachings of the inventive concept.

In the present invention, the terms “comprises”, “comprising” or “includes” indicate that various ingredients can be used together in the mixture or composition of the present invention. Thus, the term “consisting essentially of” is encompassed by the term “contains”, “includes”, or “including.”

Unless otherwise clearly stated and limited, the terms “connect”, “connected” and “connecting” in the present invention should be understood in a broad sense. For example, it can be a fixed connection, or it can be connected through an intermediary medium, or it can be two elements. Internal connectivity or interaction between two components. For those of ordinary skill in the art, the specific meanings of the above terms in this application can be understood according to specific circumstances.

For example, if an element (or component) is referred to as being on, coupled to, or connected to another element, then the one element can be directly formed on, coupled to, or connected to the other element. Either connected to them, or there can be one or more intervening elements between them. On the contrary, if the expressions “directly on,” “directly coupled to,” and “directly connected to” are used, there are no intervening element. Other words used to describe the relationship between elements should be interpreted similarly, such as “between” and “directly between”, “attached” and “directly attached”, “adjacent” and “directly adjacent” and so on.

In addition, it should be noted that the words “front”, “back”, “left”, “right”, “upper” and “lower” used in the following description refer to the directions in the drawings. The words “inside” and “outside” are used to refer to directions toward or away from, respectively, the geometric center of a particular component. It will be understood that, herein, these terms are used to describe the relationship of one element, layer or region to another element, layer or region as illustrated in the figures. These terms are intended to encompass other orientations of the device in addition to the orientation depicted in the figures.

Other aspects of the invention will be apparent to those skilled in the art from the disclosure herein.

In order to explain the embodiments of the present invention more clearly, the specific implementation modes of the present invention will be described below with reference to the accompanying drawings. Obviously, the drawings in the following description are only some embodiments of the present invention. For those of ordinary skill in the art, without exerting creative efforts, other drawings can also be obtained based on these drawings, and obtain other embodiments.

It should also be noted that the diagrams provided in the following embodiments are only schematically illustrating the basic concept of the present application. The drawings only show the components related to the present application and are not based on the number, shape and number of components during actual implementation. Dimension drawing, in actual implementation, the type, quantity and proportion of each component can be arbitrarily changed, and the component layout type may also be more complex. For example, the thicknesses of elements in the drawings may be exaggerated for clarity.

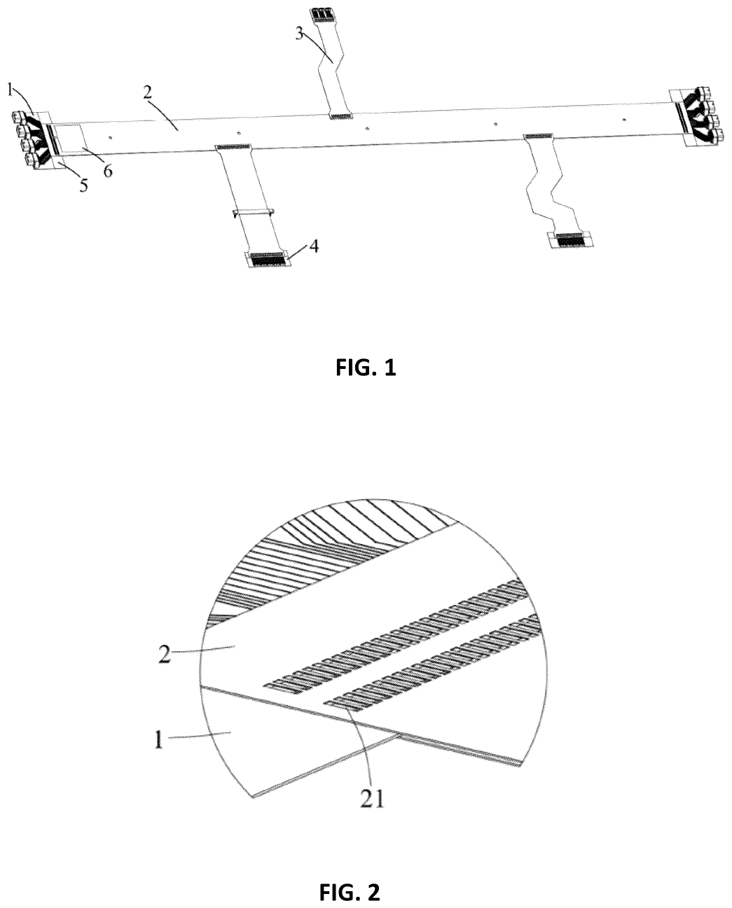

As shown in FIG. 1, the present invention provides an aluminum flexible printed circuit board (Flexible Printed Circuit, FPC) assembly, including:
The first circuit board 1 and the second circuit board 4;
Main circuit board 2, the main circuit board 2 is a flexible printed circuit board, and both ends of the main circuit board 2 are connected to the first circuit board 1;
Branch circuit board 3, the branch circuit board 3 is a flexible printed circuit board, and one end of several branch circuit boards 3 is connected to the surface of the main circuit board 2, and the other end is connected to the second circuit board 2. Circuit board 4 is connected;
The main circuit board 2 has a first aluminum circuit layer and a first insulating layer, and the branch circuit board 3 has a second aluminum circuit layer and a second insulating layer.

The above technical solution, in addition to using a flexible first aluminum circuit layer in the main circuit board 2 to replace the traditional copper core wire harness, reduces the production cost and overall weight, and solves the problem of the high cost, heavy weight and time-consuming repair of the traditional copper core wire harness. In addition to the problem of difficulty in disassembly, a plurality of branch circuit boards 3 are connected to the side of the main circuit board 2 to enable more flexible connection with the first circuit board 1.

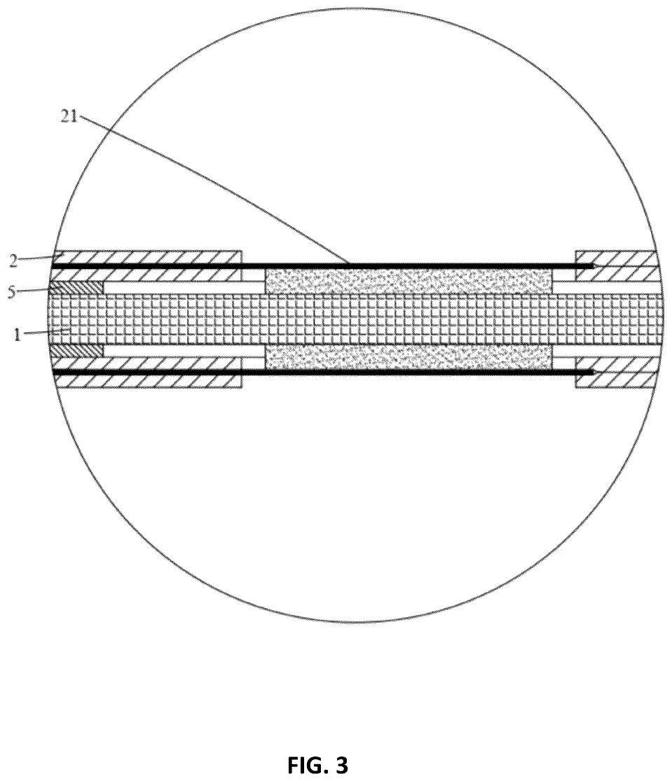

For example, as shown in FIGS. 1-5, the first circuit board 1 includes a plurality of first connectors and first pads respectively provided corresponding to the plurality of first connectors.

In this technical solution, the first circuit board 1 and the second circuit board 4 can be made of existing printed circuit boards (PCBs). The first connector can be selected from existing connector structures in the technical field according to actual needs, as long as the expected connection purpose can be achieved. The first connector is fixed to the connector through conventional welding and other processes. The first soldering pad, the built-in circuit in the first circuit board 1 connects the first soldering pad one by one to the corresponding soldering pins of the first connector, thereby realizing the first soldering pad and conduction between the first connectors.

In this technical solution, the main circuit board 2 includes upper and lower first insulating layers and a first aluminum circuit layer disposed between the upper and lower insulating layers. The first insulating layer has a number of through holes that are processed at the end to expose the end of the aluminum circuit at the corresponding position to form the second pad 21; the positions of the through holes are arranged in a “W” shaped array, so that the adjacent third two bonding pads 21 are staggered along the length direction of the aluminum circuit to avoid problems such as bridging between the adjacent second bonding pads 21 during the welding process. In addition, the above arrangement can reduce the number of adjacent aluminum circuits. The spacing between the lines facilitates a compact design. The first pad and the subsequent third, fourth and fifth pads all adopt the same structure as the second pad 21. The second soldering pad 21 provided at the end of the main circuit board 2 is connected to the corresponding first soldering pad, and an insulating sealant 5 is provided at the connection. The second soldering pad 21 can be connected to the corresponding first soldering pad by welding. The first pad is connected.

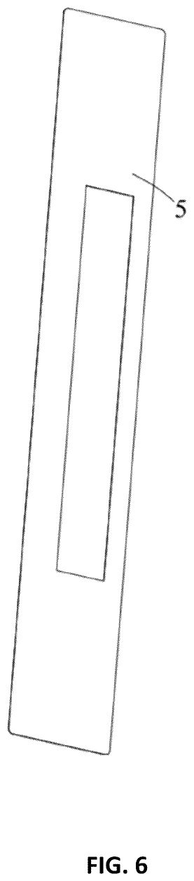

For example, as shown in FIGS. 1-6, the first circuit board 1 is preferably a double-layer printed circuit board. In an application scenario where a large number of tiny electronic components are densely packed, a double-layer printed circuit board is better than a single-layer printed circuit board. Printed circuit boards offer clear advantages. The connection method between the first pad of the double-layer printed circuit board and the soldering pin of the connector has been described in the previous section and will not be described again here.

In this technical solution, the main circuit board 2 is a double-layer flexible printed circuit board, specifically including an upper circuit board and a lower circuit board. Both the upper circuit board and the lower circuit board include upper and lower first layers. An insulating layer and a first aluminum circuit layer disposed between the upper and lower first insulating layers. The upper circuit board and the lower circuit board are joined through a glue layer, and the glue layer can be set to M4914-020 strong double-sided foam tape from 3M Company. The first aluminum circuit layer in the lower circuit board is connected to each of the double-layer printed circuit boards, and the first aluminum circuit layer in the upper circuit board is connected to the corresponding branch circuit Plate 3. The large gaps between the aluminum circuits of the first aluminum circuit layer of the upper circuit board and the lower circuit board are filled with reinforcing plates to improve the overall strength of the first aluminum circuit layer. The branch circuit board 3 can be electrically connected through the corresponding first circuit board 1.

In this technical solution, the ends of the double-layer printed circuit board and the double-layer flexible printed circuit board are pasted with insulating sealant 5, and the insulating sealant 5 is provided with a welding window, and the welding window is used to expose the first welding pad and the second welding pad 21 are used to facilitate the welding of the first welding pad and the second welding pad 21. The welding process includes conventional processes such as laser welding process. After welding, use insulating tape or the like to fix the welding joint, and insulate and cover the second pad 21 on the side facing away from the first circuit board 1 to fully improve its insulation performance; wherein, the surface of the second pad 21 is welded with a nickel-plated aluminum sheet or sintered with a layer of metallic nickel layer, so that the aluminum second bonding pad 21 can be directly laser welded to the first bonding pad, and the nickel-plated aluminum sheet or sintered nickel layer is filled in the second bonding pad due to the thickness of the first insulation layer and the first gap formed between the pads improves the stability and reliability of the welding.

For example, both ends of the main circuit board 2 can be fixedly connected to the corresponding first circuit board 1 through second connectors (not shown), so that the second pad 21 is connected to the corresponding first circuit board 1. The first pad is connected.

In this technical solution, the second connector can directly use the clip recorded in Chinese patent CN218334370U or other existing connector structures, which can realize the first aluminum circuit layer and the first aluminum circuit layer in the main circuit board 2. The circuit boards 1 are fixed to each other and the second pad 21 and the first pad are connected.

For example, as shown in FIGS. 1 and 5, a plurality of third pads 22 for connecting the branch circuit boards 3 are provided on the surface of the main circuit board 2.

In this technical solution, the forming process of the third bonding pad 22 is the same as the forming process of the second bonding pad 21, that is, the aluminum circuits of the first aluminum circuit layer are exposed at the corresponding positions of the first insulating layer to form the third bonding pad 22. Three pads are used to connect the aluminum circuits of the second aluminum circuit layer in the branch circuit board 3.

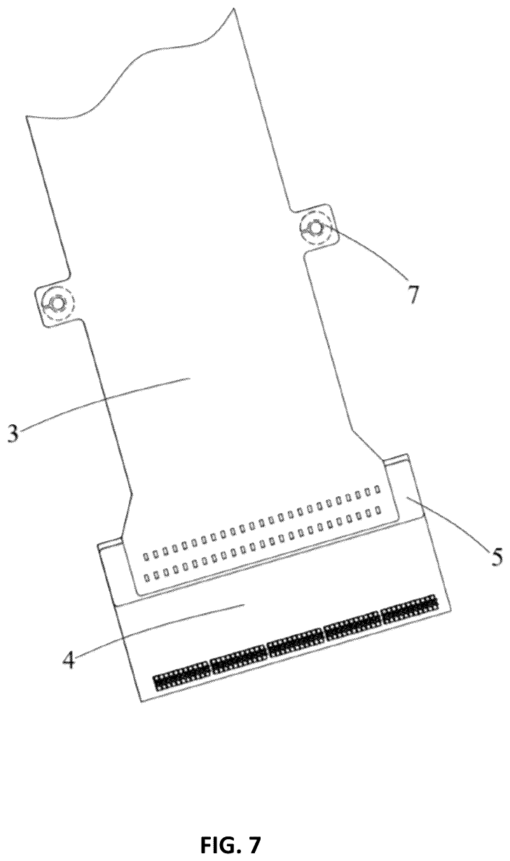

For example, as shown in FIGS. 1 and 7, both ends of the aluminum circuits of the second aluminum circuit layer in the branch circuit board 3 form fourth pads on the surface of the branch circuit board 3 respectively. The fourth bonding pads 31 are respectively connected to the corresponding third bonding pads and the second circuit board 4.

In this technical solution, the forming process of the fourth bonding pad 31 is the same as the forming process of the second bonding pad 21, that is, the aluminum circuits of the second aluminum circuit layer are exposed on the second insulation layer. A fourth solder pad is formed at a corresponding position at the end of the third solder pad 22 for connecting the third solder pad 22 and the second circuit board 4.

For example, as shown in FIGS. 1 and 7, the fourth bonding pad 31 is welded to the corresponding third bonding pad 22, and an insulating sealant 5 is provided at the welding point.

In this technical solution, the welding process and structure between the third bonding pad 22 and the fourth bonding pad 31 are the same as the welding process and structure between the first bonding pad and the second bonding pad 21.

For example, the end of the branch circuit board 3 can also be fixed to the corresponding main circuit board 2 through a third connector, so that the fourth soldering pad 31 is connected to the corresponding third soldering pad 22.

In this technical solution, the third connector can directly use existing connectors and other structures to achieve fixation between the branch circuit board 3 and the main circuit board 2, and connect the fourth pad 31 and the third welding pad 31 to the main circuit board 2. The disks 22 are connected.

For example, as shown in FIGS. 1 and 7, the second circuit board 4 includes a plurality of fourth connectors and fifth pads respectively provided corresponding to the fourth connectors.

In this technical solution, the fourth connector can choose existing connectors or conventional structures such as wire harness clips according to actual needs, and is welded to the fifth pad through conventional welding and other processes, and is used for branch circuit boards 3 and 3 for external docking.

For example, as shown in FIGS. 1 and 7, the fifth pad is welded to the corresponding fourth pad 31, and an insulating sealant 5 is provided at the welding point.

In this technical solution, the welding process and structure between the fifth and fourth bonding pads 31 are the same as the welding process and structure between the first and second bonding pads 21.

For example, the end of the branch circuit board 3 can also be fixed to the corresponding second circuit board 4 through a fifth connector, and the fourth soldering pad is connected to the corresponding fifth soldering pad.

In this technical solution, the fifth connector can also directly use existing connectors and other structures to achieve fixation between the branch circuit board 3 and the second circuit board 4, and connect the fourth pad 31 with the corresponding fifth connector. The pads are connected.

For example, as shown in FIG. 1, the main circuit board 2 is provided with a ground layer 6.

In this technical solution, a welding pin protrudes from one end of the ground layer 6 and is welded to the ground signal pad in the first pad by laser welding, and then a PSA double-sided PSA double-layer with conductive and low-resistance characteristics is used. The surface tape is pasted on the surface of the main circuit board 2.

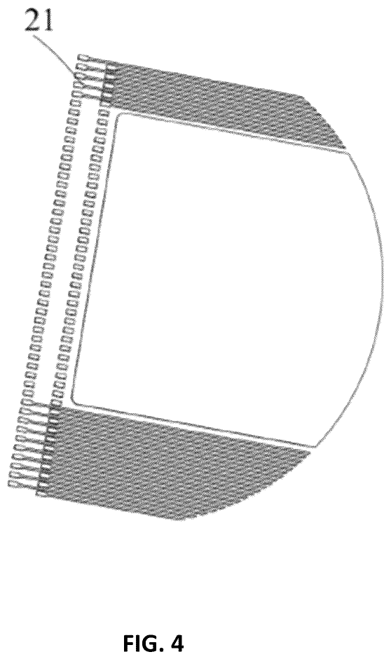

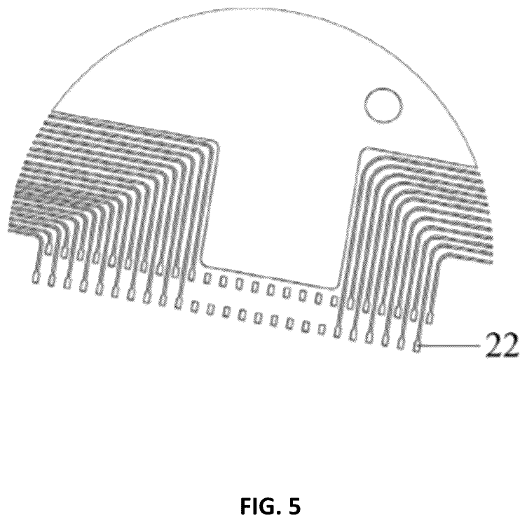

For example, as shown in FIGS. 4 and 5, the main circuit board 2 and the branch circuit board 3 are both provided with spare pads.

In this technical solution, the main circuit board 2 and the branch circuit board 3 are equipped with vacant lines and/or pads, which are used as spare pads to facilitate the subsequent repair of the circuit using a handheld welding machine, soldering or conductive tape, or resoldering.

For example, as shown in FIGS. 1 and 7, the main circuit board 2 and/or the branch circuit board 3 are provided with a mounting portion 7.

In this technical solution, two bosses are reserved in the first insulation layer or the second insulation layer during the cutting process, and holes are drilled to be used as the installation part. In order to ensure the strength, metal gaskets can be embedded in the installation part to match the pressure plate and rivets and other direct fixation of the flexible circuit board in the desired position.

The invention also provides a method for preparing an aluminum flexible printed circuit board assembly, which includes the following steps:
S1. Prepare a first circuit board 1, a main circuit board 2, a branch circuit board 3 and a second circuit board 4. The first circuit board 1 includes a plurality of first connectors and a plurality of first connectors respectively provided corresponding to the first connectors. The first soldering pad, the second circuit board 4 includes a plurality of fourth connectors and fifth soldering pads respectively arranged corresponding to the fourth connectors, the main circuit board 2 is a flexible printed circuit board, including at least two layers of first soldering pads. An insulating layer and a plurality of first aluminum circuit layers arranged between the two first insulating layers. The branch circuit board 3 is a flexible printed circuit board, including two second insulating layers and a plurality of first aluminum circuit layers arranged between the two second insulating layers and the second aluminum circuit layer;
Among them, the preparation process of the main circuit board 2 includes the following steps:
S11. Use a laser cutting machine to cut the first aluminum circuit layer and the first insulation layer, and after the cutting is completed, roll them into rolls for use;
S12. Install the first aluminum circuit layer coil and the first insulation layer coil to the corresponding retracting and unwinding shaft of the roll-to-roll laser processing machine;
S13. Use a CCD (Charge coupled Device) alignment camera to align the first aluminum circuit layer and the corresponding first insulation layer;
S14. The first aluminum circuit layer and the first insulation layer are hot-pressed and formed at a temperature of 140° C. through a heating wheel to form a single-layer circuit board structure;
S15. Repeat steps S11 to S14;
S16. Bond two or more single-layer circuit board structures through double-sided adhesive layers to form a circuit board structure with two or more layers;
Wherein, the main circuit board 2 can have a single-layer, double-layer or multi-layer circuit board structure. When the main circuit board has a single-layer circuit board structure, in steps S11 to S14, two first insulating layers can be directly hot-pressed. When the circuit board has a double-layer circuit board structure, just continue to follow steps S15 and S16. By analogy, it can also be a multi-layer circuit board structure. The branch circuit board 3 can also be made by the above steps. The first aluminum circuit layer and the second aluminum circuit board. The specific wiring structure of the circuit layer can refer to the wiring structure of the existing circuit board.
S2. Fix and connect the two ends of the main circuit board 2 to the corresponding first circuit board 1, wherein the two ends of the main circuit board 2 are respectively provided with second pads, and the first circuit board 1 is provided with There are first pads, the second pads are connected to the corresponding first pads, and a number of third pads for connecting the branch circuit boards 3 are provided on the surface of the main circuit board 2;
S3. Fix and connect one end of the branch circuit board 3 to the second circuit board 4;
S4. Fix and connect the other end of the branch circuit board 3 to the main circuit board 2;
Wherein, the two ends of the branch circuit board 3 are respectively provided with fourth soldering pads, the second circuit board 4 is provided with a fifth soldering pad, and the two fourth soldering pads are respectively connected to the corresponding third soldering pad and the fifth soldering pad.

For example, the laser cutting machine is a roll-to-roll laser cutting machine. After the waste material is removed, the first aluminum circuit layer is formed.

In this technical solution, different release films are pasted on both sides of the aluminum circuit layer. After the cutting is completed, the first aluminum circuit layer and the waste material are separated and rolled up with different release films.

For example, the laser cutting machine uses an ablation method to cut the first aluminum circuit layer.

In this technical solution, if the pattern is too complex or the material is too thin to exclude waste, ablation cutting can be used: cutting the pattern with a laser, and irradiating the unnecessary part (waste) with the laser to vaporize the irradiated material. Finally, a laser is used to clean up the remaining dirt during the vaporization process.

For example, the first soldering pad and the fifth soldering pad are respectively soldered with nickel-plated aluminum sheets and soldered to the corresponding main circuit board 2 and branch circuit board 3.

Exemplarily, the second bonding pad and the fourth bonding pad connected to the second circuit board 4 are sintered with a nickel layer.

Exemplarily, the sintering of the nickel layer includes the following steps:
S17. First cover the aluminum foil surface of the second pad or the fourth pad with a layer of nickel paste through silk screen printing;
S18. Use the laser to heat the aluminum sheet coated with nickel paste with a continuous power of 15 W to 250 W, leaving the nano-nickel powder to cover the aluminum sheet.
S19. Use the laser to reheat the surface layer of the aluminum sheet with nano-nickel powder at a continuous power of 200 W to 500 W;

The aluminum pad can be directly laser welded to the copper pad, and the nickel-plated aluminum sheet or sintered nickel layer fills the second and fourth pads due to the thickness of the first insulating layer and the second insulating layer. The gap formed between the corresponding first pad and the fifth pad improves the stability and reliability of welding.

In summary, the aluminum flexible printed circuit board assembly has a simple structure and can completely replace the circuit board of the copper core wire harness. The aluminum flexible circuit board is used to replace the copper core wire harness, which reduces production costs and overall weight, and facilitates disassembly and line maintenance. repair.

Based on this application, those skilled in the art will appreciate that one aspect described herein can be implemented independently of any other aspect, and that two or more of these aspects can be combined in various ways. For example, apparatuses may be implemented and/or methods practiced using any of the numbers and aspects set forth herein. Additionally, such apparatus may be implemented and/or methods practiced using other structures and/or functionality in addition to one or more of the aspects set forth herein.

Those skilled in the art know that in addition to implementing the system and its various devices, modules, and units provided by the present invention in the form of pure computer-readable program codes, the system and its various devices provided by the present invention can be completely implemented by logically programming the method steps, modules, and units implement the same functions in the form of logic gates, switches, application-specific integrated circuits, programmable logic controllers, and embedded microcontrollers. Therefore, the system and its various devices, modules and units provided by the present invention can be regarded as a kind of hardware component, and the devices, modules and units included in it for realizing various functions can also be regarded as hardware components. The structure; the devices, modules, and units used to implement various functions can also be regarded as either software modules for implementing methods or structures within hardware components.

It should be noted that the above embodiments can be freely combined as needed. The above are only preferred embodiments of the present invention. It should be noted that those skilled in the art can make several improvements and modifications without departing from the principles of the present invention. These improvements and modifications can also be made. should be regarded as the protection scope of the present invention.

All documents mentioned in this application are incorporated by reference in this application to the same extent as if each individual document was individually incorporated by reference. In addition, it should be understood that after reading the above content of the present invention, those skilled in the art can make various changes or modifications to the present invention, and these equivalent forms also fall within the scope defined by the appended claims of this application.

What is claimed is:

1. An aluminum flexible printed circuit board assembly, characterized by comprising:
the first circuit board and the second circuit board;
a main circuit board, the main circuit board is a flexible printed circuit board, and both ends of the main circuit board are connected to the first circuit board;
branch circuit board, the branch circuit board is a flexible printed circuit board, and one end of several branch circuit boards is connected to the surface of the main circuit board, and the other end is connected to the second circuit board respectively;
the main circuit board has a first aluminum circuit layer and a first insulating layer, and the branch circuit board has a second aluminum circuit layer and a second insulating layer.

2. The aluminum flexible printed circuit board assembly according to claim 1, wherein the first circuit board includes a plurality of first connectors and first pads respectively corresponding to the plurality of first connectors.

3. The aluminum flexible printed circuit board assembly according to claim 2, wherein the two ends of the first aluminum circuit layer respectively form second soldering pads on the surface of the main circuit board, and the second soldering pads are formed on the surface of the main circuit board. The pad is connected to the corresponding first pad.

4. The aluminum flexible printed circuit board assembly according to claim 3, wherein the second pad is welded to the corresponding first pad, and an insulating sealant is provided at the welding point.

5. The aluminum flexible printed circuit board assembly according to claim 3, wherein both ends of the main circuit board are fixedly connected to the corresponding first circuit board through second connectors, so that the third circuit board The two bonding pads are connected to the corresponding first bonding pad.

6. The aluminum flexible printed circuit board assembly according to claim 1, wherein a plurality of third pads for connecting branch circuits are provided on the surface of the main circuit board.

7. The aluminum flexible printed circuit board assembly according to claim 6, characterized in that: both ends of the second aluminum circuit layer form fourth soldering pads on the surface of the branch circuit board, and the fourth soldering pads are formed on the surface of the branch circuit board. The pads are respectively connected to the corresponding third pads and the second circuit board.

8. The aluminum flexible printed circuit board assembly according to claim 7, wherein the fourth pad is welded to the corresponding third pad, and an insulating sealant is provided at the welding point.

9. The aluminum flexible printed circuit board assembly according to claim 7, wherein the branch circuit is fixed to the corresponding main circuit through a third connector, and the fourth solder pad is connected to the corresponding third solder pad.

10. The aluminum flexible printed circuit board assembly according to claim 7, wherein the second circuit board includes a plurality of fourth connectors and fifth pads respectively corresponding to the fourth connectors.

11. The aluminum flexible printed circuit board assembly according to claim 10, wherein the fifth pad is welded to the corresponding fourth pad, and an insulating sealant is provided at the welding point.

12. The aluminum flexible printed circuit board assembly according to claim 10, wherein the branch circuit is fixed to the corresponding second circuit board through a fifth connector, and the fourth pad is connected to the corresponding second circuit board. The fifth pad.

13. The aluminum flexible printed circuit board assembly according to claim 1, wherein the main circuit board is provided with a ground layer.

14. The aluminum flexible printed circuit board assembly according to claim 1, wherein the main circuit board and the branch circuit board are both provided with spare pads.

15. The aluminum flexible printed circuit board assembly according to claim 1, wherein the main circuit board and/or the branch circuit board are provided with a mounting portion.

16. A method for preparing an aluminum flexible printed circuit board assembly according to claim 1, characterized in that it includes the following steps:
S1. Prepare a first circuit board, a main circuit board, a branch circuit board and a second circuit board, wherein the first circuit board includes a plurality of first connectors and first pads respectively provided corresponding to the first connectors, the second circuit board includes a plurality of fourth connectors and fifth pads respectively provided corresponding to the fourth connectors. The main circuit board is a flexible printed circuit board, including at least two layers of first insulating layers and a plurality of first insulating layers. The first aluminum circuit layer between the two first insulating layers, the branch circuit board is a flexible printed circuit board, including two second insulating layers and a plurality of second aluminum circuit layers disposed between the two second insulating layers;
S2. Fix and connect the two ends of the main circuit board to the corresponding first circuit board, wherein the two ends of the main circuit board are respectively provided with second soldering pads, and the first circuit board is provided with a first soldering pad. pad, the second pad is connected to the corresponding first pad, and a plurality of third pads for connecting branch circuit boards are provided on the surface of the main circuit board;
S3. Fix one end of the branch circuit board and connect it to the second circuit board;
S4. Fix the other end of the branch circuit board and connect it to the main circuit board;
wherein, fourth soldering pads are respectively provided at both ends of the branch circuit board, and fifth soldering pads are provided on the second circuit board. The two fourth soldering pads are respectively connected to the corresponding third soldering pads and the fifth soldering pads.

17. The preparation method according to claim 16, characterized in that the preparation process of the main circuit board includes the following steps:
S11. Use a laser cutting machine to cut the first aluminum circuit layer and the first insulation layer, and after the cutting is completed, roll them into rolls for use;
S12. Install the first aluminum circuit layer coil and the first insulation layer coil to the corresponding retracting and unwinding shaft of the roll-to-roll laser processing machine;
S13. Use the CCD alignment camera to align the first aluminum circuit layer and the corresponding first insulation layer;
S14. The first aluminum circuit layer and the first insulation layer are hot-pressed and formed at a temperature of 140° C. through a heating wheel to form a single-layer circuit board structure;
S15. Repeat steps S11 to S14;
S16. Bond two or more single-layer circuit board structures through a double-sided adhesive layer to form a circuit board structure with two or more layers.

18. The preparation method according to claim 16, characterized in that: the first soldering pad and the fifth soldering pad are respectively soldered with nickel-plated aluminum sheets and soldered to the corresponding main circuit board and branch circuit board.

19. The preparation method according to claim 16, wherein the second bonding pad and the fourth bonding pad connected to the second circuit board are sintered with a nickel layer.

20. The preparation method according to claim 19, characterized in that: the sintering of the nickel layer includes the following steps:
S17. First cover the aluminum foil surface of the second pad or the fourth pad with a layer of nickel paste through silk screen printing;
S18. Use the laser to heat the aluminum sheet coated with nickel paste with a continuous power of 15 W to 250 W, leaving the nano-nickel powder to cover the aluminum sheet; and
S19. Use the laser to reheat the surface layer of the aluminum sheet with nano-nickel powder at a continuous power of 200 W to 500 W.
